(19) United States
(12) Patent Application Publication
(10) Pub. No.: US 2014/0035691 A1
(43) Pub. Date: Feb. 6, 2014

(54) CAPACITIVE DIVIDER STRUCTURE

(71) Applicants: Pasquale Lamanna, Cannes (FR); Davide Orifiamma, Valbonne (FR); Cristian Pavao Moreira, Frouzins (FR)

(72) Inventors: Pasquale Lamanna, Cannes (FR); Davide Orifiamma, Valbonne (FR); Cristian Pavao Moreira, Frouzins (FR)

(73) Assignee: Cambridge Silicon Radio Limited, Cambridge (GB)

(21) Appl. No.: 13/563,427

(22) Filed: Jul. 31, 2012

(51) Int. Cl. H03L 7/099; H03B 5/12; H02M 3/06

(52) U.S. Cl. 331/36 C; 307/109; 331/117 FE

(57) ABSTRACT

A capacitive divider structure, comprising: a first plurality of capacitive devices, each being selectively controlled in accordance with a first input control signal so as to alter the effective capacitance of the capacitive divider structure by a first amount; a second plurality of capacitive devices coupled in parallel with the first plurality of capacitive devices, each being selectively controlled in accordance with a second input control signal so as to alter the effective capacitance of the capacitive divider structure by a second amount; and at least one series capacitive device arranged in series with the second plurality of capacitive devices, such that the second amount is less than the first amount.

### TECHNICAL FIELD

The present invention relates to capacitive divider structures, and to circuits employing the same, such as oscillators.

### BACKGROUND OF THE INVENTION

Digital controlled oscillators (DCOs) are oscillators whose output frequency is controlled not by an analogue input control voltage but by a digital control word. Since DCOs are controlled by a digital quantized input word, they cannot generate a continuous range of frequencies as can their analogue counterparts, voltage controlled oscillators (VCOs).

One prior solution to this problem has been to create an “effective” DCO by combining a digital-to-analogue converter (DAC) and a conventional VCO. In this arrangement, the digital control word is converted to the analogue domain by means of a current steering or voltage mode DAC, and the analogue value is then fed to a conventional VCO.

Another technique feeds the digital control word directly to the DCO by using a sigma-delta modulation scheme (such as described in U.S. Pat. No. 6,658,748). This technique spreads the high frequency quantization noise which is then filtered by the low pass filtering properties of the controlled oscillator.

Wireless application standards, however, require a very high frequency resolution to meet standard specifications and neither of these techniques is sufficient to meet those requirements. As the output frequency of an LC oscillator is given by

$${f}_{out} = \frac{1}{2 π \sqrt{L C}} ,$$

a high frequency resolution requires correspondingly precise control of the capacitance and inductance values. For example, if the value of the output frequency is to be controlled through step changes in the capacitance value, in order to comply with current wireless standards the magnitude of this step size needs to be, in some cases, lower than a few femto Farads (fF). However, achieving extremely low capacitance values is difficult, since parasitic and/or electrical phenomena become predominant over the capacitance value itself.

### BRIEF SUMMARY OF THE INVENTION

According to a first aspect of the present invention, there is provided a capacitive divider structure, comprising: a first plurality of capacitive devices, each being selectively controlled in accordance with a first input control signal so as to alter the effective capacitance of the capacitive divider structure by a first amount; a second plurality of capacitive devices coupled in parallel with the first plurality of capacitive devices, each being selectively controlled in accordance with a second input control signal so as to alter the effective capacitance of the capacitive structure by a second amount; and at least one series capacitive device arranged in series with the second plurality of capacitive devices, such that the second amount is less than the first amount.

The capacitive divider circuit may be employed in an oscillator circuit, which itself may be employed in a locked-loop circuit, such as a phase-locked loop or a frequency-locked loop. The locked-loop circuit may be employed in a wireless system, such as a transmitter or a receiver.

In another aspect of the invention there is provided a method of calibrating an oscillator in a locked-loop circuit, the oscillator comprising an inductor, and a capacitive divider structure comprising a first plurality of capacitive devices, each being selectively controlled in accordance with a first input control signal so as to alter the effective capacitance of the capacitive divider structure by a first amount; a second plurality of capacitive devices coupled in parallel with the first plurality of capacitive devices, each being selectively controlled in accordance with a second input control signal so as to alter the effective capacitance of the capacitive structure by a second amount; and at least one series capacitive device arranged in series with the second plurality of capacitive devices, such that the second amount is less than the first amount. The method comprises: locking the locked-loop circuit to an output frequency; forcing a device of the first plurality of capacitive devices to switch states; and while still locked at the output frequency, measuring a number of devices of the second plurality of devices that have switched states as a consequence.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following descriptions taken in conjunction with the accompanying drawing, in which:

FIG. 1 shows a digital-controlled oscillator according to embodiments of the present invention;

FIG. 2 shows a capacitive divider structure according to embodiments of the present invention;

FIG. 3 shows a phase-locked loop according to embodiments of the present invention;

FIG. 4 is a graph showing changes in capacitance according to embodiments of the present invention; and

FIG. 5 is a flow chart of a calibration method according to embodiments of the present invention.

### DETAILED DESCRIPTION OF THE INVENTION

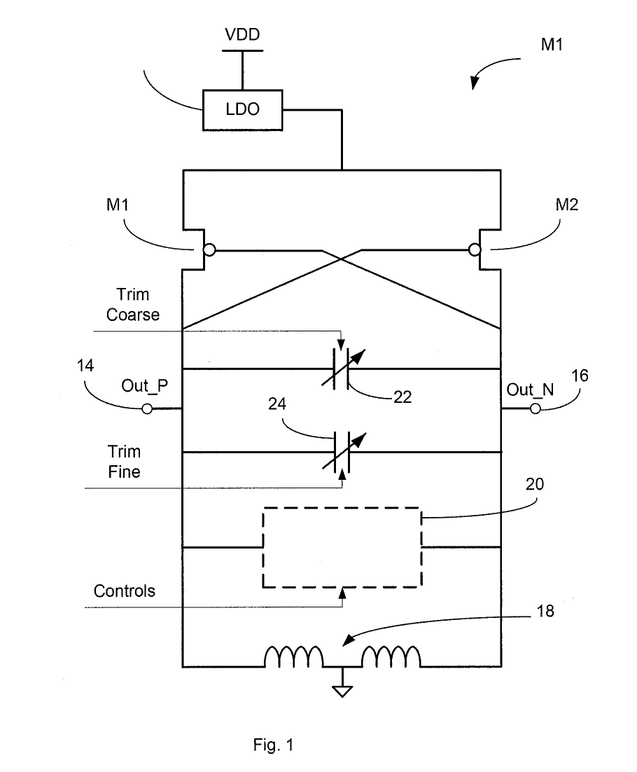

FIG. 1 shows a digital-controlled oscillator (DCO) 10 according to embodiments of the present invention.

The DCO 10 comprises an input power rail VDD which, in the illustrated circuit, is coupled to the oscillating components via a low drop-out regulator 12. As will be familiar to those skilled in the art, the low drop-out regulator 12 provides a regulated DC voltage at its output. In alternative arrangements a non-LDO regulator may be used instead, or no regulator may be needed if the supply voltage is stable enough.

The output of the LDO 12 is split into two parallel conductive paths, each terminating at a reference voltage (which in the illustrated circuit is ground). A terminal 14 coupled to a first path provides a positive output (Out_P in the diagram); and a further terminal 16 coupled to a second path provides a negative output (Out_N in the diagram).

The oscillating components of the DCO 10 comprise an inductor 18 coupled between the supply voltage and a reference voltage (which in the illustrated circuit is ground). In the illustrated embodiment the inductor 18 has a centre-tapped butterfly structure (that is, the inductor is effectively split into two components having equal inductance L/2 on each of the parallel conductive paths between the supply voltage and the reference voltage); however, those skilled in the art will appreciate that the inductor could be arranged in other ways without substantively affecting operation of the circuit or departing from the scope of the invention.

According to embodiments of the present invention, a capacitive divider structure 20 is coupled between the two conductive paths. As will be familiar to those skilled in the art, this parallel connection, together with the series-connected inductor, provides an oscillation at a frequency of

$${f}_{out} = \frac{1}{2 π \sqrt{L C}} ,$$

where C is the capacitance of the capacitive divider structure 20 and the trim capacitors 22, 24 described below. The capacitive divider structure is controlled according to one or more digital control signals, as will be described below, to provide a variable capacitance (and thus an output frequency) which can be closely and accurately controlled.

Two capacitors are coupled between the two conductive paths of the DCO 10. A first variable capacitor 22 has a capacitance which can be varied in discrete steps according to a control signal Trim_Coarse. The discrete steps have a relatively large value and thus the capacitance of the first variable capacitor can be varied at a relatively coarse resolution. A second variable capacitor 24 has a capacitance which can be varied in discrete steps according to a control signal Trim_Fine. The discrete steps have a relatively small value (relative to the variation of the first variable capacitor 22) and thus the capacitance of the second variable capacitor can be varied at a relatively fine resolution. In an embodiment, each of the variable capacitors 22, 24 comprises a capacitor bank with individual capacitive elements being selectively activated to provide a variable capacitance. The capacitor banks may be arranged in a binary-weighted scheme. The control signals Trim_Coarse and Trim_Fine may be digital signals.

As will be familiar to those skilled in the art, the trim capacitors 22, 24 can be employed such that a particular capacitance value of the capacitive divider structure provides an expected frequency output from the oscillator 10. That is, the trim capacitors are set to take certain coarse and fine capacitance values during a calibration phase and are not thereafter changed during operation of the oscillator.

The DCO 10 further comprises two cross-coupled transistors M1 and M2. A source/drain terminal of the transistor M1 is coupled to the power supply rail VDD; a corresponding drain/source terminal of the transistor M1 is coupled to the inductor 18. Likewise, a source/drain terminal of the transistor M2 is coupled to the power supply rail VDD, and a corresponding drain/source terminal of the transistor M2 is coupled to the inductor 18. The transistors are “cross-coupled” in the sense that the gate terminal of the transistor M1 is coupled to the drain terminal of the transistor M2, and the gate terminal of the transistor M2 is coupled to the drain terminal of the transistor M1. In an embodiment, the transistors M1, M2 are low-threshold PMOS transistors. As will be understood by those skilled in the art, in operation the transistors provide a negative resistance to the LC tank.

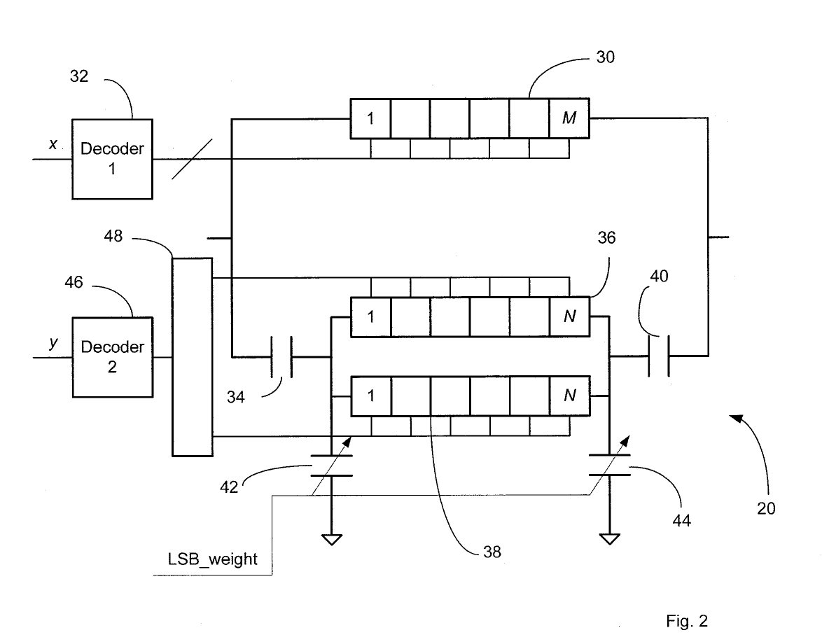

FIG. 2 shows the capacitive divider structure 20 in more detail. The capacitive divider structure 20 comprises two conductive paths connected in parallel between the two conductive paths of the oscillator 10 shown in FIG. 1.

In a first conductive path, a bank 30 of capacitive devices is provided which can be controlled to provide a relatively coarse change in the effective capacitance of the divider structure 20. This is termed hereinafter the “coarse” bank 30. Each capacitive device can be controlled in a binary fashion so as to provide a first capacitance value when a control signal is at a first logical level (e.g. 0), or a second, different capacitance value when the control is at a second logical level (e.g. 1). In embodiments of the present invention, each capacitive device can be a varactor (also called a varactor diode). As will be familiar to those skilled in the art, varactors are operated reverse-biased so that no current flows; however, their capacitance can be made to vary according to the applied bias voltage. The capacitance of each capacitive device is given by Cᵥ as follows:

Cᵥ=Cₘᵢₙ+Control*ΔC
Control=0,1
   where Cₘᵢₙ is the lower of the two capacitance values provided by each capacitive device, and ΔC is a positive change in capacitance as a result of the control signal (which controls the bias voltage across the capacitive device). ΔC can be made very small depending on the size of the capacitive device and the control of the bias voltage.

Each of the capacitive devices in the coarse bank 30 is connected in parallel with each other, such that the activation of one capacitive device adds ΔC to the overall effective capacitance of the divider structure 20. The coarse bank 30 may comprise M identical capacitive devices (where M is an integer greater than one), such that the maximum effective capacitance of the coarse bank 30 is M*(CₘᵢₙΔC). In embodiments of the invention may be set as the minimum achievable capacitance for a given integration technology, as this provides the potential for the greatest accuracy in the control of the capacitance and consequently the output frequency. Alternatively, Cₘᵢₙ may be set at a higher value if such high performance is not required.

A decoder 32 is provided, which receives a digital control word and generates corresponding control signals for each of the capacitive devices in the coarse bank 30. In one embodiment, the decoder 32 provides binary to thermometric decoding. Thermometric signals are digital signals having a particular bit, such that all bits having a lower weight than the particular bit are at a first logical level (i.e. 1) and all bits having a greater weight that the particular bit are at a second logical level (i.e. 0). Examples of thermometric numbers include 001111, 000111, 000011, etc. Thus in this embodiment the decoder 32 receives a binary coded control signal having x bits (where x is an integer), and converts the binary signal to a thermometric signal having 2^{x}−1 bits. Assuming there is no redundancy in the signal, the number of capacitive devices in the coarse bank M is equal to 2^{x}−1, and thus each bit in the control signal corresponds to a particular capacitive device. Each capacitive device in the coarse bank 30 can therefore be controlled to take one of two capacitance values as required.

The second conductive path of the capacitive divider structure 20 provides the “fine” control of the capacitance (relative to the coarse control provided by the coarse bank 30). A capacitor 34 is connected in series with two banks of capacitive devices 36, 38 (termed the primary fine bank and the secondary fine bank respectively), with a first node of the capacitor 34 coupled to the output Out_P 14 and a second node of the capacitor coupled to respective nodes of the primary and secondary fine banks 36, 38. The primary and secondary fine banks 36, 38 are therefore coupled in parallel with each other. A second capacitor 40 is also connected in series with the primary and second fine banks 36, 38, with a first node of the capacitor 40 coupled to the output Out_N 16, and a second node coupled to the opposite nodes of the fine banks 36, 38. In the illustrated circuit, each of the capacitors 34, 40 has a capacitance equal to C. Two further capacitors 42, 44 are provided in parallel with the fine banks 36, 38. One capacitor 42 is coupled between a first node of the fine banks 36, 38 and a reference voltage (which in the illustrated circuit is ground), and another capacitor 44 is coupled between a second (opposite) note of the fine banks 36, 38 and the reference voltage. Each capacitor 42, 44 has a capacitance denoted 2C_{f}, which is variable in accordance with a control signal LSB_weight.

The primary and secondary fine banks 36, 38 are equally sized, each having N capacitive devices (where N is a positive integer greater than one). Structurally, the fine banks 36, 38 are similar to the coarse bank 30. In embodiments of the present invention, therefore, each capacitive device can be a varactor (or varactor diode). Each capacitive device can be controlled in a binary fashion so as to take one of two capacitance values, Cₘᵢₙ or (Cₘᵢₙ+ΔC). Each of the capacitive devices in the fine banks 36, 38 is connected in parallel with each other. In the illustrated circuit, each capacitive device in the fine banks 36, 38 has a capacitance equal to Cᵥ (i.e. equal to the capacitance of the capacitive devices in the coarse bank 30). In operation, the primary fine bank 36 is used to adjust the capacitance of the capacitive divider structure in response to one or more control signals; the secondary fine bank 38 is used to provide a frequency offset in the event that the primary fine bank 36 nears either full or zero saturation (i.e. all or nearly all capacitive devices are switched on or off). This operation will be explained in greater detail below.

A second decoder 46 is provided, which receives a digital control word and generates corresponding control signals for each of the capacitive devices in the fine banks 36, 38. In one embodiment, the decoder 46 provides a control signal to a selector 48, which itself receives arbiter signals. Control signals can then be provided to one or both of the primary and secondary fine banks as required and as will be described in more detail below. The decoder 46 may perform binary to thermometric decoding in a similar fashion to the decoder 32. Thus the decoder 46 may receive a binary coded control signal having y bits (where y is an integer), and convert the binary signal to a thermometric signal having 2^{y}−1 bits. Assuming there is no redundancy in the signal, the number of capacitive devices in each fine bank N is equal to 2^{y}−1, and thus each bit in the control signal corresponds to a particular capacitive device. Each capacitive device in the fine banks 36, 38 can therefore be activated or not as required.

As described above, the coarse bank of capacitive devices 30 provides a variable capacitance in the range from M*Cₘᵢₙ to M*(Cₘᵢₙ+ΔC) with a resolution of ΔC. The effective capacitance of the second conductive path (including the fine banks 36, 38) is equal to:

$${C}_{eff} = \frac{{C}_{s} ( {\sum }_{i = 1}^{N} {C}_{v , i} + {C}_{f} )}{2 ( {\sum }_{i = 1}^{N} {C}_{v , i} + {C}_{f} ) + {C}_{s}} ,$$

where the capacitances of the primary fine bank 36 are summed over all N devices. Thus it can be seen that the presence of the series capacitors 34, 40 and the capacitors 42, 44 reduces the effective capacitance of the fine banks 36, 38 such that switching one of the capacitive devices in those banks results in a much smaller change in the overall effective capacitance than switching one of the capacitive devices in the coarse bank 30, despite them having the same nominal capacitance.

By differentiation of the equation above, the activation of a capacitive device (Cᵥ) inside the primary fine bank 36 results in a change in capacitance of the capacitive divider structure as follows:

$$Δ {C}_{eff} = \frac{{C}_{s}^{2}}{{( 2 {\sum }_{i = 1}^{N} {C}_{v , i} + 2 {C}_{f} + {C}_{s} )}^{2}} \times Δ C .$$

This results in a change in the frequency output of

$$Δ f = \frac{{C}_{s}^{2} \times Δ C}{4 π C \sqrt{L C} \times {( 2 {\sum }_{i = 1}^{N} {C}_{v , i} + 2 {C}_{f} + {C}_{s} )}^{2}} ,$$

where C is the total capacitance of the oscillator circuit (i.e. including the trim capacitors 22, 24 as well as the capacitance of the capacitive divider circuit 20). Thus, it can be seen that for every change in capacitance of the primary fine bank 36, ΔC, the change in effective capacitance for the capacitive divider structure is equal to ΔC attenuated by a factor

$$\frac{{C}_{s}^{2}}{{( 2 {\sum }_{i = 1}^{N} {C}_{v , i} + 2 {C}_{f} + {C}_{s} )}^{2}} .$$

While ΔC can be in the order of a few femtoFarads, the change in ΔC_{eff} is much smaller. Moreover, the size of that change can be varied by varying the value of C_{f}. By appropriate control of the signal LSB_weight, it is possible to decouple the minimum frequency resolution from process variation. Typically, the value of LSB_weight (and therefore C_{f}) will be set to a particular value during a calibration phase, and maintained at that value throughout use of the oscillator 10. In an embodiment, the value of C_{f} is set such that the change of capacitance as a result of switching all of the capacitive devices in the primary fine bank 36 (i.e. the dynamic range of the primary fine bank 36) is equal to or greater than the change in capacitance as a result of switching one of the devices in the coarse bank 30 of capacitive devices. In order to keep the number of devices in the primary fine bank 36 low, in an embodiment the range of the primary fine bank 36 may be set less than twice the change in capacitance as a result of switching one of the devices in the coarse bank 30 of capacitive devices.

The effective capacitance of the capacitive divider structure 20 is thus comprised of a coarse component provided by the coarse bank 30, and a fine component provided by the combination of capacitors 34, 40, 42, 44 and the fine banks 36, 38. As the coarse components and the fine components are in parallel with each other, the two capacitances add. Digital code words are provided in order to activate a certain number of devices in the coarse bank 30 and in the fine banks 36, 38 so as to achieve a particular capacitance and therefore a particular output frequency.

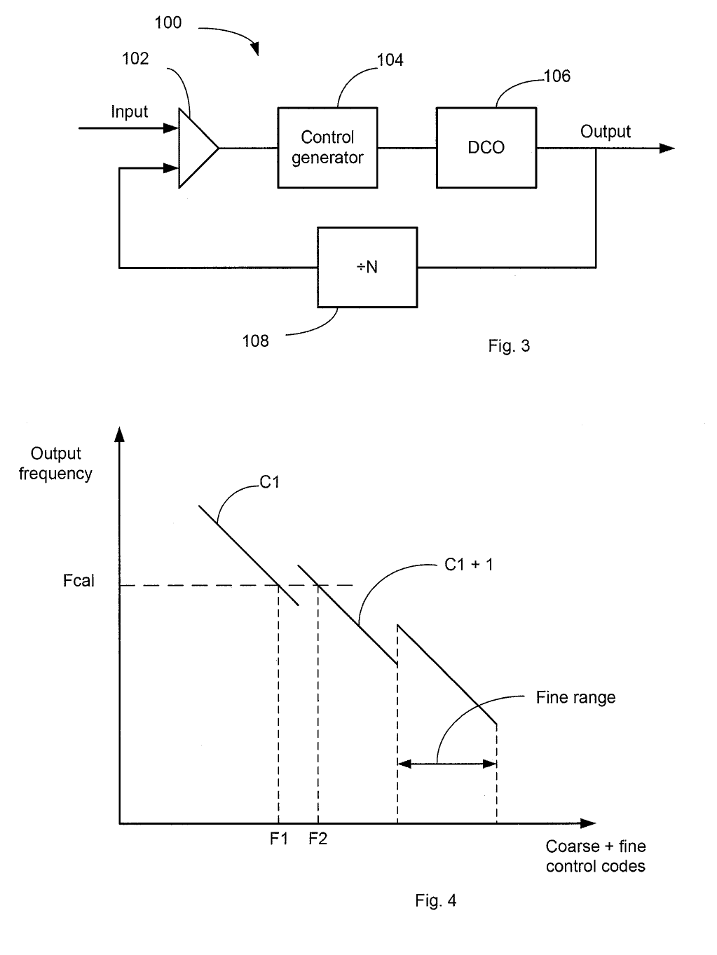

As is known in the art, the frequency output of the oscillator 10 varies with changing temperature. When implemented as part of a locked-loop circuit (e.g. see FIG. 3), the control signals will vary so as to compensate for this drift in output frequency. Specifically, the capacitance of the capacitive divider structure will gradually increase or decrease as required. Eventually, this will lead to the situation where the primary fine bank 36 is fully saturated at its minimum or maximum capacitance value, with the next increase or decrease in capacitance causing the least significant bit in the coarse bank 30 to change. This results in the simultaneous or near simultaneous switching of all capacitive devices in the primary fine bank 36, as well as one device in the coarse bank 30. If there is any mismatch between the devices in the respective bank, this can lead to error in the output of the oscillator. Moreover, if the temperature (and hence output frequency) remains constant at or around this level, switching of the LSB in the coarse bank 30 can occur frequently and thus severely reduce the accuracy of the oscillator 10.

The oscillator 10 therefore operates most reliably when the primary fine bank 36 is at or near the middle of its dynamic range, i.e. when approximately half the capacitive devices in the primary fine bank 36 are switched high and the other half are switched low. This ensures that switching of the lease significant bit in the coarse bank 30 is minimized.

In embodiments of the invention, upper and lower threshold values may be set on either side of that optimum position at the centre of the dynamic range, and the incoming code word compared to the threshold values. If the code word is greater than the upper threshold value or lower than the lower threshold value, the primary fine bank 36 is nearing either full or zero saturation. According to embodiments of the invention, if the control word falls outside either threshold value, arbiter signals are adjusted to activate one or more capacitive devices in the secondary fine bank 38. This creates a low frequency offset and ensures the primary fine bank 36 always operates between the upper and lower threshold values.

For example, assume the thermometric control signal applied to the primary fine bank 36 has a range from 0 to 100, and has lower and upper threshold values of 10 and 90, respectively. If the incoming binary control signal specifies that the thermometric control signal for the primary fine bank should be 95, this capacitance value can be split using the arbiter signals with a control signal applied to the primary fine bank of 90, and a control signal applied to the secondary fine bank of 5. The secondary fine bank 38 can then be employed to adjust the capacitance value of the capacitive divider structure 20 further as required.

As will be clear from the discussion above, the oscillator 10 may be employed in a locked-loop circuit such as a phase-locked loop (PLL) or a frequency-locked loop (FLL). FIG. 3 shows such a locked-loop circuit 100.

An input signal having an input frequency and an input phase is provided to a comparator 102, where it is compared with a feedback signal having a feedback frequency and a feedback phase. If the circuit 100 is a PLL, the phase of the two signals is compared and an output signal generated; if the circuit 100 is a FLL, the frequency of the two is compared and an output signal generated. A control generator 104 receives the output of the comparator 102 and generates digital binary control signals for a digital controlled oscillator 106, in particular to control the capacitance values of the DCO as described above. The DCO 106 of FIG. 3 may therefore be similar to the DCO 10 described with respect to FIG. 1.

The DCO 106 generates an output signal, and this is provided as the output of the circuit 100. In addition, the signal is fed back via a feedback loop to the comparator 102. Optionally, a divider 108 can divide the frequency of the feedback signal such that the circuit 100 acts to multiply the frequency of the input signal.

Those skilled in the art will appreciate that numerous features have been omitted from FIG. 3 where they are not crucial to an understanding of the invention. For example, locked-loop circuits will typically employ a low-pass filter.

FIG. 4 is a graph showing how the output frequency varies with changing control signals (i.e. changing capacitance). As can be seen, the range of the primary fine bank 36 allows a change in frequency which is greater than the change in frequency as a result of a change in the least significant bit of the coarse bank 30. That is, the range of frequencies allowed by the coarse bank 30 set with a number C₁ of devices active, overlaps with the range of frequencies allowed by the coarse bank 30 set with a number C₁+1 of devices active.

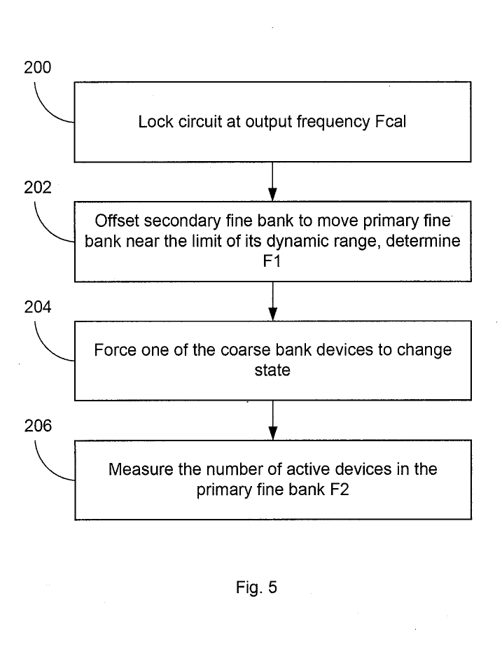

FIG. 5 shows a method of calibrating the oscillator 10 (and particularly the capacitive divider structure 20) when employed inside a locked-loop circuit such as that described with respect to FIG. 3.

In step 200, the locked-loop circuit 100 is operated so that it locks to an output signal having an output frequency F_{cal}. The digital control signal provided to the coarse bank 30 of capacitive devices controls a number C₁ of those devices to be set to a high capacitance value; the digital control signal provided to the primary fine bank 36 of capacitive devices control a number of those devices to be set to a high capacitance value.

In step 202, the secondary fine bank 38 of capacitive devices is controlled to provide an offset such that the primary fine bank 36 of devices is operated near the limits of its dynamic range, i.e. either most of the devices in the primary fine bank are at their low capacitance values, or most are at their high capacitance values. If the primary fine bank 36 is already operating near the upper or lower limit of its range, no action needs to be taken. If the primary fine bank 36 is operating near the mid-point of its dynamic range, a number of the secondary fine bank 38 devices may be switched to a high capacitance value such that some of the primary fine bank 36 devices automatically switch to a low capacitance value to compensate, and the primary fine bank 36 moves nearer to its lower limit. The circuit 100 remains locked at the same output frequency. Following this step, a number F₁ of devices in the primary fine bank 36 are at their high capacitance values. We can therefore write

F_{cal}=K_{coarse}C₁+K_{fine}F₁,

where K_{coarse} and K_{fine} are constants of proportionality for variation of the number of “active” devices in the coarse bank 30 and the primary fine bank 36, respectively.

In step 204, the number of “active” devices in the coarse bank 30 is forced to change by one. That is, one of the devices is either switched to a high capacitance value or a low capacitance value by manipulation of the control signal for the coarse bank 30. If the primary fine bank 36 was previously near its lower limit, one of the coarse devices is switched low; if the primary fine bank 36 was previously near its upper limit, one of the coarse devices is switched high. However, the circuit 100 remains locked at the same frequency F_{cal}. With the coarse bank capacitance changed, and the secondary fine bank 38 held constant, the capacitance of the primary fine bank 38 must change to compensate. As the dynamic range of the primary fine bank 36 is greater than the least significant bit of the coarse bank 30, the primary fine bank 30 does not saturate following this change. Thus we can write

F_{cal}=K_{coarse}(C₁+1)+K_{fine}F₂,

where F₂ is the number of devices now “active” in the primary fine bank 36.

The quantity F₂−F₁ is thus equal to the number of least significant bits in the primary fine bank 36 that make up one least significant bit in the coarse bank 30 (step 206). To avoid problems with noise, the loop may be allowed to remain in lock for a programmable length of time and the value of F₂ averaged over that time. A first-order, unity gain IIR low pass filter is sufficient to perform this function.

This calibration procedure, using a locked-loop circuit, is significantly quicker, easier and more accurate than conventional processes, which tend to measure the change in capacitance directly.

The present invention thus provides a capacitive divider structure, an oscillator and a locked-loop circuit employing the same, and a method of calibrating the capacitive divider structure. By using a digitally-switched capacitance bank inside a capacitive divider structure it is possible to achieve a very high frequency resolution at the output of digital controlled oscillator, using capacitive devices of reasonable and feasible size. The introduction of capacitors (C₁) in parallel with the fine banks of capacitive devices decouples the minimum frequency resolution (LSB step) from process variation. The use of the locked-loop circuit (in its closed loop arrangement) to extract frequency information from the oscillator control signal makes this calibration very accurate.

Those skilled in the art will appreciate that various amendments and alterations can be made to the embodiments described above without departing from the scope of the invention as defined in the claims appended hereto.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A capacitive divider structure, comprising:
a first plurality of capacitive devices, each being selectively controlled in accordance with a first input control signal so as to alter the effective capacitance of the capacitive divider structure by a first amount;
a second plurality of capacitive devices coupled in parallel with the first plurality of capacitive devices, each being selectively controlled in accordance with a second input control signal so as to alter the effective capacitance of the capacitive structure by a second amount; and
at least one series capacitive device arranged in series with the second plurality of capacitive devices, such that the second amount is less than the first amount.

2. The capacitive divider structure according to claim 1, wherein the first amount is denoted a, and wherein the second plurality of capacitive devices is collectively capable of altering the effective capacitance of the capacitive divider structure by a third amount γ, with α≦γ≦2α.

3. The capacitive divider structure according to claim 1, further comprising at least one variable capacitive device connected in parallel with the second plurality of capacitive devices, having a first node connected between the second plurality of capacitive devices and the at least one series capacitive device, and a second node coupled to a reference voltage, the capacitance of the at least one variable capacitive device being variable in order to vary the second amount.

4. The capacitive divider structure according to claim 1, further comprising a third plurality of capacitive devices arranged in parallel with the second plurality of capacitive devices, and in series with the at least one series capacitive device.

5. The capacitive divider structure according to claim 4, wherein each capacitive device of the third plurality of capacitive devices can be selectively activated to offset an effective capacitance of the second and third pluralities of capacitive devices such that the second control signal lies within an upper threshold value and a lower threshold value.

6. The capacitive divider structure according to claim 1, wherein each of the first plurality of capacitive devices and each of the second plurality of devices comprises a varactor diode.

7. The capacitive divider structure according to claim 1, wherein each of the first plurality of capacitive devices and each of the second plurality of capacitive devices can be controlled to take one of two capacitance values.

8. The capacitive divider structure according to claim 1, wherein the first and second input control signals comprise first and second digital code words.

9. The capacitive divider structure according to claim 8, wherein the first and second digital code words are derived from a single input signal.

10. The capacitive divider structure according to claim 8, further comprising at least one decoder for decoding the digital code words from a binary format to a thermometric format.

11. An oscillator circuit, comprising:
an inductor; and
a capacitive divider structure according to claim 1, coupled to the inductor.

12. A phase-locked loop, comprising an oscillator according to claim 11.

13. A method of calibrating an oscillator in a locked-loop circuit, the oscillator comprising an inductor, and a capacitive divider structure comprising a first plurality of capacitive devices, each being selectively controlled in accordance with a first input control signal so as to alter the effective capacitance of the capacitive divider structure by a first amount; a second plurality of capacitive devices coupled in parallel with the first plurality of capacitive devices, each being selectively controlled in accordance with a second input control signal so as to alter the effective capacitance of the capacitive structure by a second amount; and at least one series capacitive device arranged in series with the second plurality of capacitive devices, such that the second amount is less than the first amount, the method comprising:
locking the locked-loop circuit to an output frequency;
forcing a device of the first plurality of capacitive devices to switch states; and
while still locked at the output frequency, measuring a number of devices of the second plurality of devices that have switched states as a consequence.

14. The method according to claim 13, wherein the capacitive divider structure further comprises a third plurality of capacitive devices arranged in parallel with the second plurality of capacitive devices, and in series with the at least one series capacitive device, the method further comprising:
controlling the third plurality of capacitive devices such that a majority of the second plurality of capacitive devices are in the same state.
